(19) United States
(12) Patent Application Publication
(10) Pub. No.: US 2008/0084224 A1
(43) Pub. Date: Apr. 10, 2008

(54) Photoionization probe with injection of ionizing vapor

(76) Inventor: Michael Nystrom, San Jose, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/545,890

(22) Filed: Oct. 10, 2006

(51) Int. Cl. G01R 31/302

(52) U.S. Cl. 324/752

(57) ABSTRACT

A photoionization probe includes two electrodes and provides ionizable vapor in a carrier gas via a channel between the electrodes. The ionizable vapor is thereby concentrated in an aperture of the probe where it is photoionized by, for example, an ultraviolet (UV) lamp.

### BACKGROUND

Nondestructive testing (NDT) techniques are widely used in the manufacture and testing of semiconductor devices. In general, these testing techniques avoid mechanical contact with the device under test or harsh testing conditions so as to protect the device. This is particularly useful when testing delicate integrated circuits during manufacturing. For example, optical techniques such as ellipsometry are used to characterize wafers, thin films, and device structures including interfaces and multi-layer structures. Electromagnetic NDT techniques can use magnetic measurements and induced current measurements to test material properties and device operation. In still other examples, currents are generated and delivered to the device under test so as to test device functionality without making mechanical contact with the device.

### SUMMARY

In accordance with the invention, a photoionization probe includes two electrodes and provides ionizable vapor in a carrier gas via a channel between the electrodes. The ionizable vapor is thereby concentrated in an aperture of the probe where it is photoionized by, for example, an ultraviolet (UV) lamp.

### BRIEF DESCRIPTION OF THE DRAWINGS

FIG. 1 illustrates an embodiment of a photoionization probe and its use to test a device in accordance with the invention.

FIGS. 2A-2C illustrate other photoionization probe aperture assembly embodiments in accordance with the invention.

FIG. 3 illustrates an example of a testing system in accordance with the invention.

### DETAILED DESCRIPTION

The following sets forth a detailed description of the best contemplated mode for carrying out the invention. The description is intended to be illustrative of the invention and should not be taken to be limiting.

In general, photoionization probes permit the transport of current across a gas filled region or through a region in which gas is flowing. For nondestructive testing, photoionization probes serve to make electrical contact to sensitive surfaces where direct physical or mechanical contact is not desirable. Photoionization probes operate on the principle of photoionization, which is often used, for example, in photoionization detectors (PIDs) in gas chromatography devices. Photoionization uses a light source providing photons of the correct energy to ionize the target gas molecule. Various different light sources can be used (e.g., lasers, specialized lamps, light emitting diodes, etc.), but in the examples of the present application ultraviolet (UV) lamps will be illustrated.

If the energy of an incoming photon is high enough (and the molecule is quantum mechanically allowed to absorb the photon) photo-excitation can occur to such an extent that an electron is completely removed from its molecular orbital, i.e. ionization. The basic reaction can be illustrated as:

R+hv R⁺+e⁻,

where R is the target gas molecule, hv is the photon energy of the light source photons having a frequency v, R⁺ is the resulting positively charged ion, and e⁻ is the electron removed from the molecule. The ions or electrons produced by this process are collected by one or more suitable electrodes (e.g., as part of the device under test), and the current generated is therefore used to characterize the device. If the amount of ionization is reproducible for a given compound, pressure, and light source, then the current collected at the electrodes of the device under test is reproducibly proportional to the amount of that compound entering the probe. As will be discussed in greater detail below, the compounds used for photoionization probes are often aromatic hydrocarbons or heteroatom containing compounds (e.g., organosulfur or organophosphorus species) because these species have ionization potentials that are within reach of commercially available UV lamps. Typical UV lamp energies range from 8.3 to 11.7 eV. Examples of photoionization probes are disclosed in U.S. patent application Ser. No. 10/976,694, assigned to the assignee of the present application.

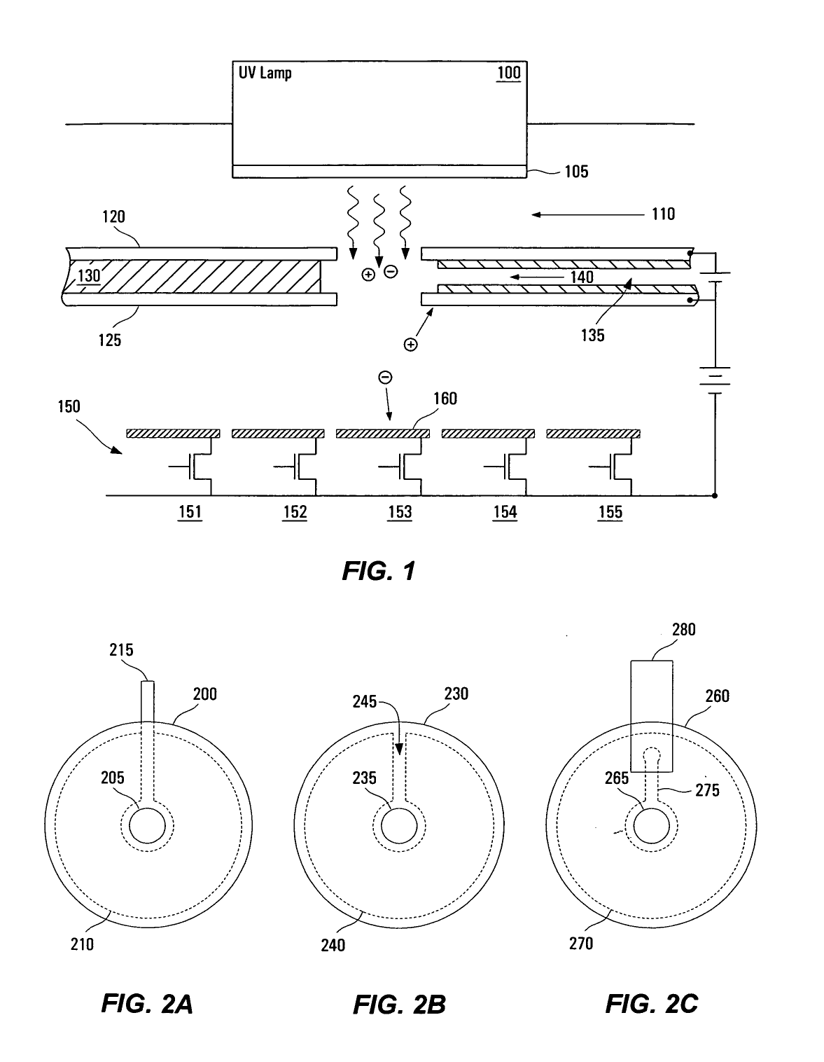

FIG. 1 illustrates an embodiment of a photoionization probe and its use to test a device in accordance with the invention. The photoionization probe includes a photoionizing light source, UV lamp 100, and a probe aperture assembly formed from electrically conducting electrodes or plates (120 and 125) separated by an insulating layer 130. Each of the components of the aperture assembly includes a hole or aperture, and the components are typically oriented as shown so that the apertures are aligned or collinear to form a continuous probe aperture. In some embodiments in accordance with the invention, the individual component apertures need not be so carefully aligned. In the FIG. 1, the size of the aperture is exaggerated for ease of illustration. Various different hole sizes, shapes, and aperture thicknesses can be implemented as will be known to those skilled in the art. An ionizable vapor, typically transported with a carrier gas, is injected through channel 140 and into the aperture. At least some portion of the ionizable vapor in the aperture absorbs photons from UV lamp 100, and is therefore ionized. A bias voltage maintained between the aperture assembly and the device under test (150-180) attracts electrons to the device under test while ionized molecules are attracted to the aperture assembly. The electrically conductive plates of the aperture assembly can be optionally biased with respect to each other, as shown, so that charged species produced within the aperture can be moved toward the bottom of the aperture and the device under test. An additional flow of carrier gas 110 (or some other relatively inert gas) can be optionally provided between UV lamp 100 and the aperture assembly to provide positive pressure limiting the flow of ionizable vapor into the region between the lamp and aperture assembly.

The photoionization probe illustrated in FIG. 1 introduces the ionizable vapor in such a way that the ionizable vapor is not exposed to UV light until it reaches the aperture. By injecting the ionizable vapor directly into the aperture, more ionized vapor is available for producing the photoionization probe's current. Moreover, the ionized vapor is relatively confined to a region where it is readily ionized. In other designs where the ionizable vapor is introduced between the aperture assembly and the UV lamp (e.g., where additional carrier gas 110 is shown), ionization can occur too far from the aperture, and thus the resulting current from charged particles attracted to the device under test is too low. This can occur because ionization occurs too close to the UV lamp, e.g., between the lamp and the electrode but not with a clear path through the aperture to the device under test. If ionizable vapor is exposed to UV light as it travels along the backside of the aperture plate to the aperture, some portion of the ionizable vapor can be “consumed” (e.g., undergo an irreversible process) before reaching the aperture. This further impacts photoionization probe efficiency.

In order to further increase the likelihood that ionization occurs within the aperture and between plates 120 and 125, the UV lamp can be further modified. For example, window 105 is typically formed from a highly UV transparent material, such as fused silica, CaF, BaF, or sapphire. Since the diameter of the aperture is typically smaller than that of window 105, a portion of window 105 can be masked (e.g., with a surface coating or an intervening optically absorbing mask) to present UV light only to the aperture area. In still other embodiments in accordance with the invention, one or more UV-quality lenses can be used to focus light from UV lamp 100 into the aperture. By increasing the amount of UV light in the aperture, photoionization can be increased an more easily controlled, producing larger and/or more stable photoionization currents. The distance between UV lamp 100 and the aperture assembly can also be adjusted to improve photoionization within the aperture. In some embodiments in accordance with the invention, lamp window 105 is located in close proximity to conducting plate 120, e.g., a few millimeters or less. The entire device can be designed such that one or both of UV lamp 100 and the aperture assembly can be moved with respect to each other so as to adjust this spacing. Similarly, one or both of UV lamp 100 and the aperture assembly can be adjusted to vary the separation between conducting plate 125 and the device under test. In still other embodiments in accordance with the present invention, the photoionization probe and/or the material holder for the device under test can be translated with respect to each other to achieve desired spacing. Numerous different material holders, support brackets, translation devices, and the like will be known to those skilled in the art.

The photoionization probes described in the present application can be used to test various different devices. In the example of FIG. 1, the device under test is an array of driver circuits for an organic light emitting diode (OLED) display. At this stage of manufacture of the overall display device, the OLEDs are not yet present. An array of driver circuits 150 is present. For each individual OLED, there is a corresponding driver circuit (151-155). One of the terminals of the driver circuit which will connect to the OLED is unconnected at the time of test. In this example, the terminal (e.g., terminal 160) is a transparent electrode formed from the transparent conductor indium-tin oxide (ITO). In general, there is one driver circuit for each pixel and each driver circuit will contain one or more transistors.

Here, a specific one of the array of driver circuits is under test. Thus, driver circuit 153 is on during the test, while driver circuits 151, 152, 154, and 155 remain off. In typical use, the bias voltage will be applied to a suitable contact (e.g., a data or bus line for a row of pixels) so as to conduct current through the desired portion of the device. The applied electrical field accelerates charge to electrode 160. By utilizing the switching present in the driver circuits and on the display device, an individual pixel can be singled out for measurement. This is useful because the size of the probe may be much larger than an individual pixel.

As noted above, aromatic hydrocarbons can be used as the ionizable vapor for the photoionization probe. Other examples of ionizable vapor sources include solvents such as acetone (propanone), butanone, toluene, ethanol, isopropanol, and the like. The ionizable vapor is generally selected based on its ionizability for a given light source and other factors, such as cost, ease of handling, safety, etc. The carrier gas used for the ionizable vapor (and potentially for the separately supplied carrier gas 110) is typically a relatively inert gas that will not otherwise interfere with probe operation or damage the probe or the device under test. Examples include air, nitrogen (N₂), and noble gases such as argon. When used, additional carrier gas 110 is typically the same carrier gas used to supply the ionizable vapor, although this need not be the case.

The aperture assembly, including conducting plates 120 and 125, as well as insulating layer 130, can be constructed from a variety of different materials. For example, conducting plates 120 and 125 can be formed from thin sheet metal or metal foil. Various different metals can be used such as copper, gold, aluminum, and steel. The metal is selected based on its conductivity (higher conductivity is generally better), its machinability, and its compatibility with the ionizable vapor and carrier gas. Conducting plate material can also be selected to reduce the possibility of contaminating the device under test. Metallic meshes can also be used. In some embodiments, solid pieces of metal (or continuous metallic coatings) are used for the electrodes, but one or both of the aperture mouths (i.e., the side closest to the lamp and the side closest to the device under test) can be covered (or at least partially covered with metallic mesh to enhance probe operation. In other embodiments in accordance with the invention, the conducting plates are formed by electrically conductive material layers deposited on a substrate, e.g., a substrate formed by insulating layer 130. For example, conducting plates 120 and 125 can be formed from metallic thin films, conductive pastes, conductive adhesives, and the like. Numerous different electrically conducting materials will be known to those skilled in the art.

Insulating layer 130, can be similarly fabricated from various different materials such as glasses, ceramics, glass-ceramics, (e.g., Macor®), plastics, rubber, polymers, and even semiconductors. Depending on the size and shape of the assembly, and the manner in which channel 140 is provided, insulating layer 130 can be formed from a single piece of material or several pieces of material.

The size and shape of the aperture assembly can also vary. In general, the aperture assembly is disk-shaped, i.e., various components 120, 125, and 130 are themselves disk shaped, with a relatively small round aperture, e.g., 0.1 mm to 2 mm. However, other shapes can be used as desired, and each of the components need not possess the same shape. The overall thickness of the aperture assembly is typically on the order of several millimeters, but that too can vary depending on the size of the components and desired probe features. In embodiments where each of the components is a separate component, the aperture assembly can be held together using one or more of adhesives, mechanical fasteners, compression fittings, mounting brackets, and the like. FIG. 1 is schematic in nature, and so other probe components such as gas fittings, housing components, o-rings, bias-voltage contacts, etc., are not illustrated.

Additionally, the aperture assembly can be fabricated using semiconductor device and/or MEMS device fabrication processes and techniques. Examples include: photolithography techniques, thin film deposition and growth techniques, etching processes, and the like. These techniques can be used to fabricate a single aperture assembly, or multiple aperture assemblies, e.g., rows or arrays of aperture assemblies.

In order to introduce the ionizable vapor between conducting electrodes, a variety of different channel and inlet designs can be implemented. FIGS. 2A-2C illustrate several photoionization probe aperture assembly embodiments in accordance with the invention. In each of the examples of FIGS. 2A-2C, only a single channel or inlet is shown. This has been done to simply illustration. In general, any number of channels or inlets (e.g., two, three, or more) can be used. Moreover, the illustrated channels/inlets have generally linear designs. However, channels or inlets of virtually any shape and size can be used. For example, a curved or spiral channel can be used. Various combinations of linear segments can also be used, e.g., an “L” shaped channel. The illustrated channels and inlets are also shown intersecting with the center of the aperture assembly. This, too, need not be the case. Channels can be configured to open to the aperture off-center. Finally, channels and inlets are generally shown has having a constant size along their length. In other embodiments in accordance with the invention, channels can be tapered or have varying cross-section. In still other embodiments in accordance with the invention, a main channel (e.g., a straight channel or a circular channel that is concentric with the aperture) can stop just short of the aperture. One or more perforations or holes in the insulating material can then allow gas flow from the main channel into the aperture.

Turning to FIG. 2A, an aperture assembly including top electrode 200 and insulating layer 210 is shown. In this example (and those of FIGS. 2B-2C) the outer diameter of insulating layer 210 is smaller than that of top electrode 200. This need not be the case, as the respective outer diameters can be the same or transposed in relative size. The inner diameter of insulating layer 210 is larger than that of top electrode 200. While these two features can also generally have any size relationship, many embodiments will utilize electrode inner diameters that are no larger than that of the insulating layer. This will have the benefit of more directly controlling the electric field between the aperture and the device under test. As in the case of FIG. 1, feature sizes and shapes are merely illustrative, and the actual size of various features may be quite different from those shown. Inlet tube 215 is press fit into a suitably sized channel or through hole in insulating layer 210. For example, if the insulating layer is rubber, the tube can be inserted through a hole formed in the rubber layer. A separate inlet tube can be useful for connection to other gas supply plumbing or fixtures. Gas flows through inlet tube 215 into aperture 205 where it can be ionized. Various different materials (metals, plastics, polymers, etc.) can be used to fabricate inlet tube 215.

FIG. 2B shows an alternate embodiment in accordance with the present invention. Top electrode 230 and insulating layer 240 are similar to those of FIG. 2A. This aperture assembly does not, however, use a separate inlet tube. Instead, carrier gas including the ionizable vapor is transported along channel 245. The carrier gas and ionizable vapor is provided to a sealed reservoir (not shown) surrounding at least the opening to channel 245, and perhaps a larger portion or all of the periphery of the aperture assembly. The applied pressure forces the carrier gas and ionizable vapor through channel 245 and into aperture 235.

FIG. 2C shows still another embodiment in accordance with the present invention. Insulating layer 270 includes a gas transport channel 275. Instead of being fed from the edge of the aperture assembly, channel 275 is supplied from above by gas supply fitting 280 located above top electrode 260. Fitting 280 is, in turn, coupled to a carrier gas and ionizable vapor source (not shown). Gas supply fitting 280 can be a simple fitting designed to be coupled to an opening in channel 275, or it may be a more complex device including a reservoir for carrier gas and/or ionizable vapor.

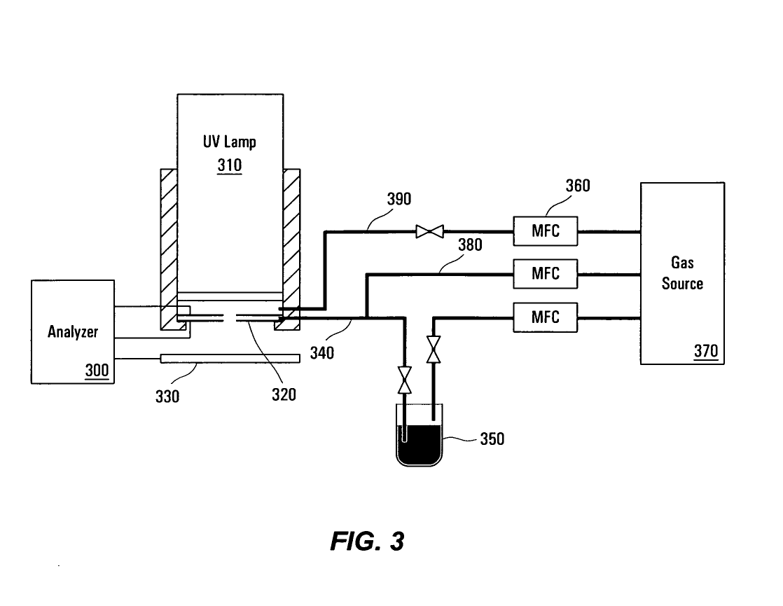

FIG. 3 illustrates an example of a testing system in accordance with the invention. The testing system includes an analyzer 300, a photoionization light source, UV lamp 310, an aperture assembly 320, and a device under test 330. As shown, analyzer 300 is coupled to both the device under test and the aperture assembly in order to provide desired bias voltages and to measure, for example, photoionization currents through the device under test.

Analyzer 300 can be specially designed test equipment for providing precise bias voltages and performing specified device measurements. In other examples, analyzer 300 is a multipurpose semiconductor parameter analyzer for advanced device characterization. Such devices typically have high resolution for low-current and low-voltage measurements, and are often designed for quasi-static capacitance vs. voltage measurements, to extract process parameters, to measure leakage characteristics, and to perform on-wafer reliability tests with built-in stressing modes. For example, analyzer can provide a desired bias voltage, e.g., ±50V, or sweep through a range of bias voltages. Similarly it can measure photoionization currents through the device under test. Such currents are typically on the order of 1 μA, but may be larger or smaller depending on device and probe characteristics.

A carrier gas containing the ionizable vapor is provided to the aperture assembly by gas inlet 340. In this example, carrier gas source 370 provides a carrier gas such as N₂ to acetone bubbler 350 where the carrier gas forces acetone vapor into inlet 340. As noted above, various different carrier gases and ionizable vapor sources can be used. The flow of carrier gas into inlet 340 is controlled by two mass flow controllers (360). One mass flow controller regulates the amount of carrier gas used to force vapor out of acetone bubbler 350, while the other regulates the additional carrier gas provided to inlet 340 via gas line 380. As noted above, additional carrier gas can be optionally provided (via gas line 390) to reduce the likelihood that ionizable vapor escapes into the area between the aperture assembly and the UV lamp. The flow of this carrier gas can be controlled by yet another mass flow controller (360). In one embodiment in accordance with the invention, the flow rate of carrier gas used to force vapor out of acetone bubler 350 is on the order of 5 standard cubic centemeters per minute (sccm), and the flow rate of additional carrier gas provided to inlet 340 via gas line 380 is on the order of 600 sccm. These values are merely illustrative, and numerous other values are possible depending upon a host of parameters and system features. While mass flow controllers are illustrated because they provide more accurate regulation of needed gas supplies, other gas flow regulation schemes can be used. For example; simple valves or pressure regulators can be used.

Basic aspects of various photoionization probes and test systems have been illustrated. Those skilled in the art will readily recognize that a variety of different types of components and materials can be used in place of the components and materials discussed above. Moreover, the description of the embodiments in accordance with the invention set forth herein is illustrative and is not intended to limit the scope of the invention as set forth in the following claims. Variations and modifications of the embodiments disclosed herein may be made based on the description set forth herein, without departing from the scope and spirit of the invention as set forth in the following claims.

What is claimed is:

1. An apparatus comprising:
a first electrode including a first aperture;
a second electrode including a second aperture;
an insulting layer between the first electrode and the second electrode, wherein the insulating layer further comprises a third aperture and a gas flow channel operable to supply gas to the third aperture; and
a photoionizing light source positioned to illuminate at least a portion of at least one of the first aperture, the second aperture, and the third aperture.

2. The apparatus of claim 1 wherein at least one of the first electrode and the second electrode further comprises at least one of: sheet metal, metal foil, an electrically conductive coating, a metallic thin film, a metallic mesh, an electrically conductive paste, and an electrically conductive adhesive.

3. The apparatus of claim 1 wherein the insulating layer further comprises at least one of: a glass, a ceramic, a glass-ceramics, a plastic, a rubber, a polymer, and a semiconductor.

4. The apparatus of claim 1 wherein the first aperture, the second aperture, and the third aperture are substantially collinear.

5. The apparatus of claim 1 further comprising:
a power supply coupled to at least one of the first electrode and the second electrode, wherein the power supply is configured to provide a voltage bias with respect to a device under test.

6. The apparatus of claim 1 further comprising:
a power supply coupled to the first electrode and the second electrode, wherein the power supply is configured to provide a voltage bias between the first electrode and the second electrode.

7. The apparatus of claim 1 further comprising at least one of:
an inlet tube coupled to the gas flow channel; and
a gas supply fitting coupled to the gas flow channel.

8. The apparatus of claim 1 wherein the photoionizing light source is an ultraviolet (UV) lamp.

9. The apparatus of claim 1 further comprising:
a lens located with respect to the photoionizing light source and at least one of the first aperture, the second aperture, and the third aperture so as to focus photoionizing light.

10. The apparatus of claim 1 further comprising:
a gas supply line located to deliver a second gas to an area between the photoionizing light source and the first electrode.

11. The apparatus of claim 1 further comprising:
a bubbler coupled to the gas flow channel, the bubbler containing a liquid for producing an ionizable vapor; and
a carrier gas source coupled to the bubbler and configured to supply carrier gas to the bubbler.

12. A method comprising:
injecting an ionizable vapor in a carrier gas into an aperture region from between a first electrode and a second electrode;
ionizing at least a portion of the ionizable vapor in the carrier gas using a photoionizing light source;
applying a bias voltage between a device under test and at least one of the first electrode and the second electrode; and
collecting electrons from the ionizable vapor in the carrier gas at the device under test.

13. The method of claim 12 further comprising:
applying a second bias voltage between the first electrode and the second electrode.

14. The method of claim 12 further comprising:
forcing the carrier gas through a liquid to produce the ionizable vapor in the carrier gas.

15. The method of claim 12 wherein the injecting further comprises:
forcing the ionizable vapor in the carrier gas through a channel in an insulating layer coupled between the first electrode and the second electrode.

16. The method of claim 12 wherein the photoionizing light source is an ultraviolet (UV) lamp.

17. The method of claim 12 further comprising:
a focusing light from the photoionizing light source at the aperture region.

18. The method of claim 12 further comprising:
measuring a current associated with electrons collected at the device under test.

19. The method of claim 12 further comprising:
supplying a second gas to an area between the photoionizing light source and the first electrode.

20. An apparatus comprising:
a means for injecting an ionizable vapor in a carrier gas into an aperture region from between a first means for providing an electric field and a second means for providing an electric field;
a means for ionizing at least a portion of the ionizable vapor in the carrier gas;
a means for applying a bias voltage between a device under test and at least one of the first means for providing an electric field and the second means for providing an electric field; and
a means for collecting electrons from the ionizable vapor in the carrier gas at the device under test.
